(19) United States
(12) Patent Application Publication
(10) Pub. No.: US 2026/0081638 A1
(43) Pub. Date: Mar. 19, 2026

(54) Automotive ethernet using asymmetric concurrent transmission (ACT)

(71) Applicant: Infineon Technologies Americas Corp., El Segundo, CA (US)

(72) Inventors: Ragnar Hlynur JONSSON, Aliso Viejo, CA (US); Seid Alireza Razavi MAJOMARD, Belmont, CA (US); Thomas Joseph HOUCK, South Lyon, MI (US); Paul FULLER, Frisco, TX (US); Mario Alejandro CASTRILLON, Cordoba (AR); Aleksei ZHEREBTCOV, Karlsruhe (DE); Amir BAR-NIV, Sunnyvale, CA (US); Bizhan ABEDINZADEH, Aliso Viejo, CA (US); Brett Anthony MCCLELLAN, Laguna Hills, CA (US); David SHEN, Saratoga, CA (US); Ehab TAHIR, Mississauga (CA); Elvio SERRANO, Cordoba (AR); Frank MCCARTHY, Alameda, CA (US); Hsiang-Ling LI, Tustin, CA (US); Peter VAN DYCK, Sunnyvale, CA (US); Xing WU, Palo Alto, CA (US); Samuel JOHNSON, Frisco, TX (US); Sina BARKESHLI, Saratoga, CA (US); Timur MINNIGALIEV, Bad Herrenalb (DE); Venkateswara C. PENUMUCHU, Pleasanton, CA (US); George A. ZIMMERMAN, Santa Clara, CA (US)

(21) Appl. No.: 19/328,150

(22) Filed: Sep. 14, 2025

Related U.S. Application Data
(60) Provisional application No. 63/695,796, filed on Sep. 17, 2024.

(51) Int. Cl. H04B 1/40; H03M 5/12; H04L 5/14

(52) U.S. Cl. CPC H04B 1/40; H03M 5/12; H04L 5/14

(57) ABSTRACT

A Physical Layer (PHY) device, for use in an Ethernet network in a vehicle, includes a link interface and a transceiver. The link interface is configured to connect to a full-duplex Ethernet link. The transceiver is configured to communicate over the full-duplex Ethernet link in a first direction using a High-Data-Rate (HDR) signal having a first data rate, and to communicate over the full-duplex Ethernet link in a second direction, opposite to the first direction, using a Low-Data-Rate (LDR) signal having a second data rate, lower than the first data rate. A frequency spectrum of the LDR signal is contained within a frequency spectrum of the HDR signal.

### CROSS-REFERENCE TO RELATED APPLICATIONS

This application claims the benefit of U.S. Provisional Patent Application 63/695,796, filed Sep. 17, 2024, whose disclosure is incorporated herein by reference.

### FIELD OF THE DISCLOSURE

The present disclosure relates generally to network communication, and particularly to methods and systems for Asymmetric Concurrent Transmission (ACT).

### BACKGROUND

Modern vehicles incorporate extensive in-vehicle networks to support communication between various electronic control units, sensors and actuators distributed throughout the vehicle. These networks facilitate the exchange of data for applications ranging from engine management and safety systems to infotainment and advanced driver assistance systems.

Automotive networks typically connect sensors such as cameras, radar units and lidar systems to central processing units or domain controllers. The communication requirements in these networks are inherently asymmetric due to the nature of the data being exchanged. Sensors generate substantial amounts of data that is transmitted to controllers for processing. For example, high-resolution cameras may produce video streams requiring data rates of several gigabits per second to maintain image quality and frame rates necessary for real-time applications.

In contrast, the communication from controllers back to sensors involves significantly lower data volumes. This reverse direction typically carries information such as control commands, configuration parameters, status requests, and synchronization signals. Such information generally requires only modest bandwidth, often in the range of hundreds of megabits per second or less.

Traditional full-duplex communication systems are designed to provide symmetric data rates in both directions, which results in inefficient utilization of available bandwidth and resources when applied to automotive networks. The substantial difference between the high-bandwidth requirements for sensor data transmission and the lower-bandwidth needs for control signaling creates an opportunity for asymmetric communication approaches that can better match the actual traffic patterns and requirements of in-vehicle networks.

The description above is presented as a general overview of related art in this field and should not be construed as an admission that any of the information it contains constitutes prior art against the present patent application.

### SUMMARY

An embodiment that is described herein provides a Physical Layer (PHY) device for use in an Ethernet network in a vehicle. The PHY device includes a link interface and a transceiver. The link interface is configured to connect to a full-duplex Ethernet link. The transceiver is configured to communicate over the full-duplex Ethernet link in a first direction using a High-Data-Rate (HDR) signal having a first data rate, and to communicate over the full-duplex Ethernet link in a second direction, opposite to the first direction, using a Low-Data-Rate (LDR) signal having a second data rate, lower than the first data rate. A frequency spectrum of the LDR signal is contained within a frequency spectrum of the HDR signal.

In some embodiments, the LDR signal is modulated with Differential Manchester Encoding (DME) modulation. In some embodiments, a transmitted power level of the LDR signal is lower than a transmitted power level of the HDR signal. In some embodiments, the full-duplex Ethernet link is a two-wire twisted-pair link. In some embodiments, the full-duplex Ethernet link is a coaxial cable.

In some embodiments, the transceiver is configured to transmit the HDR signal to the full-duplex Ethernet link, and to receive the LDR signal from the full-duplex Ethernet link. In a disclosed embodiment, the transceiver is configured to demodulate the LDR signal in the presence of the transmitted HDR signal, without applying echo cancellation. In an embodiment, the transceiver is configured to extract a LDR clock signal from the received LDR signal, to generate a HDR clock signal that is locked on the LDR clock signal, and to transmit the HDR signal in accordance with the HDR clock signal. In an example embodiment, the transceiver is configured to generate the HDR clock signal without a local crystal oscillator.

In some embodiments, the transceiver is configured to transmit the LDR signal to the full-duplex Ethernet link, and to receive the HDR signal from the full-duplex Ethernet link. In a disclosed embodiment, the transceiver is configured to demodulate the HDR signal in the presence of the transmitted LDR signal, without applying echo cancellation. In an example embodiment, a baud rate of the LDR signal is approximately 117 Mbaud.

There is additionally provided, in accordance with an embodiment that is described herein, a method for communication in an Ethernet network in a vehicle. The method includes communicating over a full-duplex Ethernet link in a first direction using a High-Data-Rate (HDR) signal having a first data rate, and communicating over the full-duplex Ethernet link in a second direction, opposite to the first direction, using a Low-Data-Rate (LDR) signal having a second data rate, lower than the first data rate. A frequency spectrum of the LDR signal is contained within a frequency spectrum of the HDR signal.

The present disclosure will be more fully understood from the following detailed description of the embodiments thereof, taken together with the drawings in which:

### BRIEF DESCRIPTION OF THE DRAWINGS

FIG. 1 is a block diagram that schematically illustrates an automotive Ethernet communication system that uses Asymmetric Concurrent Transmission (ACT), in accordance with an embodiment that is described herein;

FIGS. 2A-2C are graphs showing power spectra of ACT signals, in accordance with embodiments that are described herein;

FIGS. 3A and 3B are graphs showing power spectrum masks for ACT signals, in accordance with embodiments that are described herein;

FIGS. 4A and 4B are block diagrams that schematically illustrate example implementations of ACT transceivers, in accordance with embodiments that are described herein;

FIG. 5 is a block diagram that schematically illustrates crystal-less clock circuitry in a sensor-side ACT transceiver, in accordance with an embodiment that is described herein; and

FIG. 6 is a flow chart that schematically illustrates a method for communication using ACT, in accordance with an embodiment that is described herein.

### DETAILED DESCRIPTION OF EMBODIMENTS

### Overview

Embodiments that are described herein provide automotive Ethernet systems that enable efficient bidirectional communication over full-duplex links using asymmetric data rates. In disclosed embodiments, a pair of Ethernet Physical Layer (PHY) devices are used for connecting a sensor, e.g., a camera, to the vehicle Ethernet network. The PHY devices communicate simultaneously in both directions over a full-duplex Ethernet link, using signals having different characteristics and data rates. The asymmetric data rate configuration addresses the inherent difference in communication requirements between the sensor-to-network and network-to-sensor directions.

In the direction from the sensor to the network, the PHY devices communicate using a High-Data-Rate (HDR) signal having a first data rate. In the opposite direction, from the network to the sensor, the PHY devices communicate using a Low-Data-Rate (LDR) signal having a second data rate that is lower than the first data rate. The LDR signal operates with a frequency spectrum that is fully contained within the frequency spectrum of the HDR signal. This scheme is referred to herein as Asymmetric Concurrent Transmission (ACT). In some embodiments the LDR signal utilizes Differential Manchester Encoding (DME) modulation. In example embodiments, the baud rate (symbol rate) of the LDR signal is approximately 117 Mbaud (117 MHz, or 117M symbols/sec), e.g., 117.1875 Mbaud. The HDR signal may utilize, for example, four-level Pulse-Amplitude Modulation (PAM4).

In ACT, the LDR signal has a considerably narrower spectrum than the HDR signal. The LDR spectrum is fully contained within the spectral range occupied by the HDR signal. The two signals coexist simultaneously on the same full-duplex link, e.g., twisted pair or coaxial cable. This choice of signal design simplifies the design, implementation and integration of the PHY devices with the vehicle network. In particular, the sensor-side PHY device is simple, small, and has low cost and low power consumption, all of which are highly beneficial in vehicle networks.

For example, in some embodiments ACT PHY devices can be implemented with good performance without requiring traditional echo cancellation. Moreover, in some embodiments the sensor-side PHY device is implemented without any local crystal oscillator. Instead, the sensor-side PHY device recovers an LDR clock signal from the received LDR signal, and uses the LDR clock signal to generate an HDR clock signal used for HDR transmission. Example implementations of ACT sensor-side and network-side PHY devices are described below.

### System Description

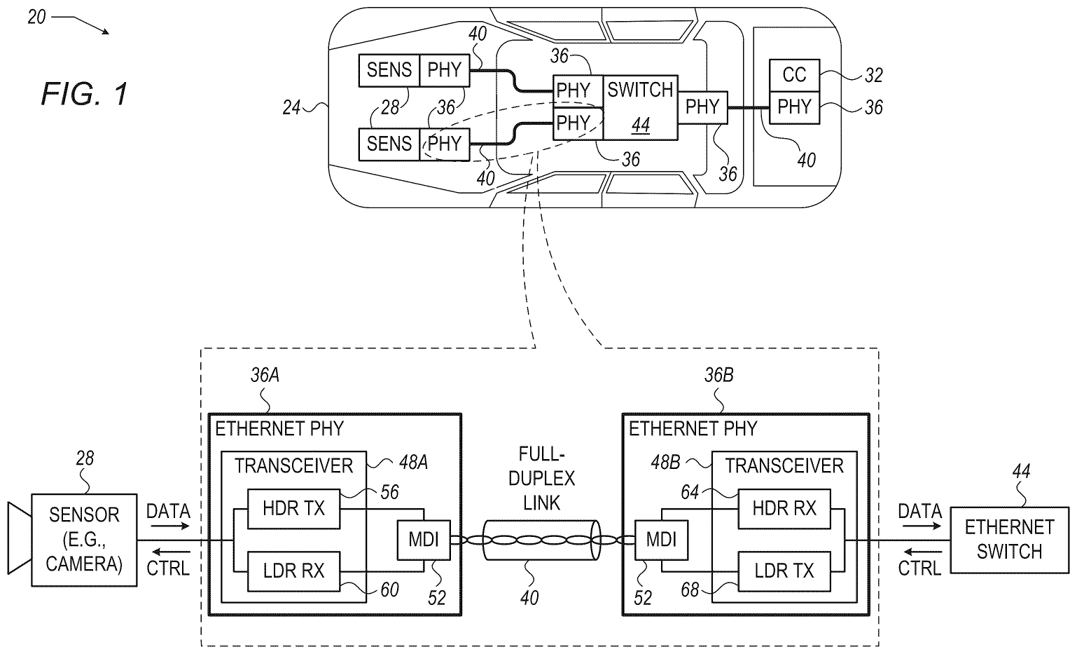

FIG. 1 is a block diagram that schematically illustrates an automotive full-duplex Ethernet communication system 20, in accordance with an embodiment that is described herein. In the present example, system 20 is installed in a vehicle 24, and comprises multiple sensors 28 that communicate with a central computer (CC) 32. In other embodiments (not seen), system 20 may be installed in an industrial network or other suitable network comprising sensors that communicate with a central computer.

In various embodiments, sensors 28 may comprise any suitable types of sensors. Several non-limiting examples of sensors comprise video cameras, velocity sensors, accelerometers, audio sensors, infra-red sensors, radar sensors, lidar sensors, ultrasonic sensors, rangefinders or other proximity sensors, and the like.

Sensors 28 and CC 32 communicate via an Ethernet network comprising multiple Ethernet PHY devices 36, multiple network links 40 and one or more Ethernet switches 44. Elements such as Medium Access Control (MAC) devices are not shown in the figure for the sake of clarity. In the present example, PHY device 36 of each sensor 28 is connected by a network link 40 to a peer PHY device 36 coupled to a port of switch 44. CC 32 is also connected to a port of switch 44 in a similar manner, via a network link 40 and a pair of PHY devices 36. Ethernet links 40 are full-duplex links, e.g., twisted-pair cables or coaxial cables.

In various embodiments, PHY devices 36 of system 20 may communicate over network links 40 at any suitable bit rate. Example bit rates are 2.5 Gb/s, 5 Gb/s or 10 Gb/s, in accordance with the IEEE 802.3ch-2020 standard (“IEEE Standard for Ethernet—Amendment 8: Physical Layer Specifications and Management Parameters for 2.5 Gbps, 5 Gbps, and 10 Gbps Automotive Electrical Ethernet,” June, 2020, which is incorporated herein by reference).

An inset at the bottom of FIG. 1 focuses on a pair of PHY devices denoted 36A and 36B connected by a full-duplex link 40. PHY devices 36A and 36B are used for connecting a sensor 28 to switch 44.

PHY device 36A is connected to a sensor 28, e.g., a camera. This PHY device is also referred to herein as a “sensor-side PHY device” or “camera-side PHY device”. PHY device 36B is connected to switch 44. This PHY device is also referred to herein as a “switch-side PHY device” or “network-side PHY device”.

Sensor-side PHY device 36A comprises a link interface, in the present example a Medium-Dependent Interface (MDI) 52, for connecting to link 40. PHY device 36A further comprises a transceiver 48A, which comprises an HDR transmitter (TX) 56 and an LDR receiver (RX) 60. Switch-side PHY device 36B comprises an MDI 52 and a transceiver 48B. Transceiver 48B comprises an HDR RX 64 and an LDR TX 68.

In the present example link 40 comprises a Shielded Twisted-Pair (STP) cable having two electrical conductors. The same pair of conductors is used for transferring both an HDR signal from HDR TX 56 (in PHY device 36A) to HDR RX 64 (in PHY device 36B), and an LDR signal from LDR TX 68 (in PHY device 36B) to LDR RX 60 (in PHY device 36A).

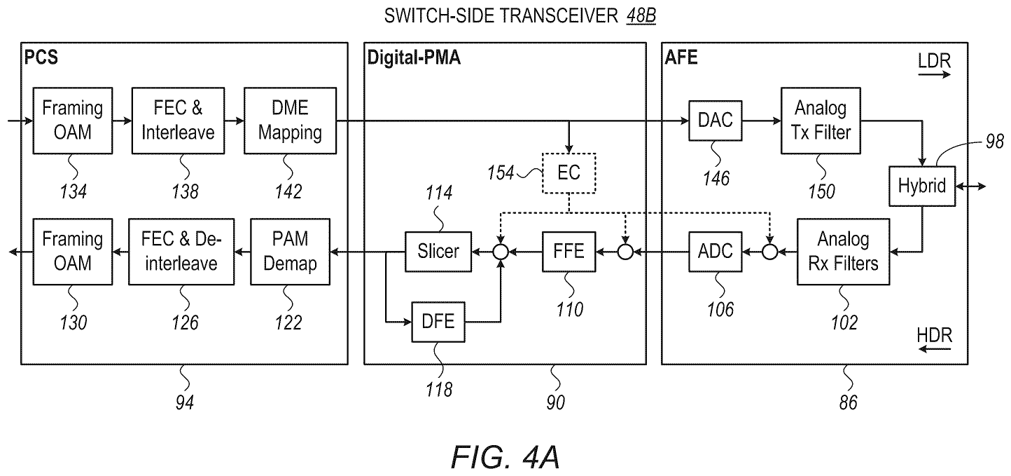

Example implementations of sensor-side transceiver 48A and switch-side transceiver 48B are described below with reference to FIGS. 4A and 4B.

### Act Power Spectra and Spectra Masks

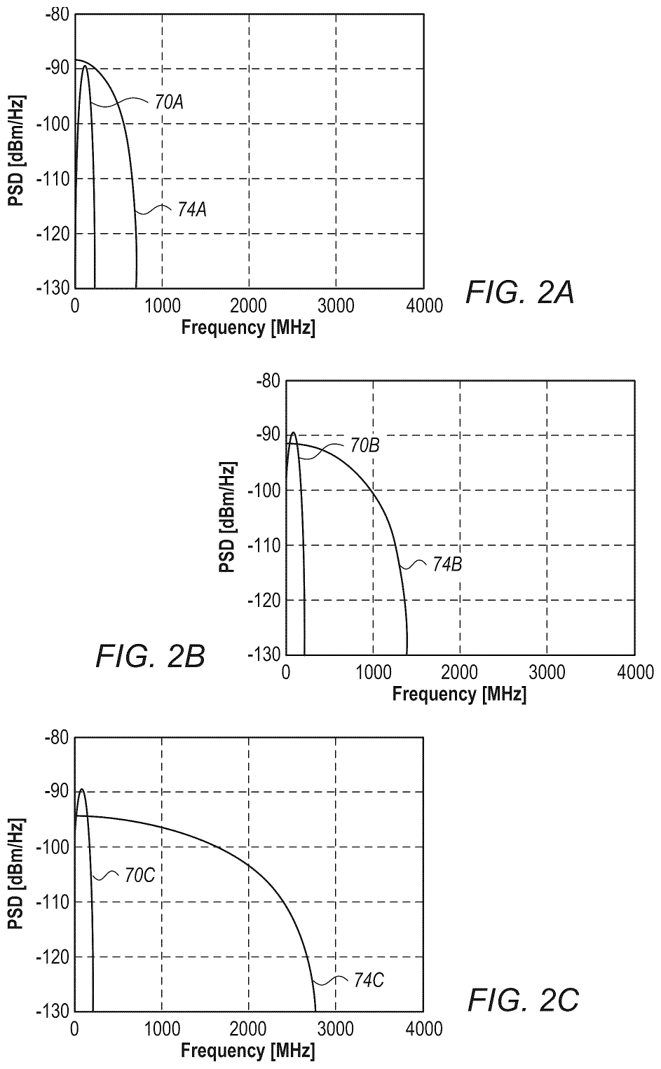

FIGS. 2A-2C are graphs showing power spectra of ACT signals, in accordance with embodiments that are described herein. In all three figures, the horizontal axis denotes frequency in MHz, and the vertical axis denotes Power Spectral Density (PSD) in dBm/Hz. Each figure comprises two plots, one showing the spectrum of the LDR signal sent from switch-side PHY device 36B to sensor-side PHY device 36A, and the other showing the spectrum of the HDR signal sent from sensor-side PHY device 36A to switch-side PHY device 36B.

In all three examples, the LDR signal is modulated using Differential Manchester Encoding (DME) modulation. In DME, one bit value (e.g., “1”) is represented by a first symbol type having a level transition in the middle of the symbol interval. The second bit value (e.g., “0”) is represented by a second symbol type having a constant level across the symbol interval. The HDR signal is modulated using 4-level Pulse-Amplitude Modulation (PAM4).

The data rate of the LDR signal in all three examples is 100 Mbps. The examples of FIGS. 2A-2C differ from one another in the data rate (and therefore the occupied bandwidth) of the HDR signal. In FIG. 2A the data rate of the HDR signal is 2.5 Gbps; in FIG. 2B the data rate of the HDR signal is 5 Gbps; and in FIG. 2C the data rate of the HDR signal is 10 Gbps.

In FIG. 2A, a plot 70A shows the spectrum of the LDR signal, and a plot 74A shows the spectrum of the HDR signal. In FIG. 2B, a plot 70B shows the spectrum of the LDR signal, and a plot 74B shows the spectrum of the HDR signal. In FIG. 2C, a plot 70C shows the spectrum of the LDR signal, and a plot 74C shows the spectrum of the HDR signal.

As seen, the spectra of the LDR and HDR signals fully overlap—The spectrum of the LDR signal is fully contained within the spectral range occupied by the HDR signal.

Recall that both signals coexist simultaneously on link 40. Therefore, HDR RX 64 needs to demodulate the received HDR signal in the presence of the LDR signal. Similarly, LDR RX 60 needs to demodulate the received HDR signal in the presence of the HDR signal. In both cases, the HDR and LDR receivers are configured to demodulate their respective signals with good performance, due to the fact that the LDR signal occupies only a small portion of the bandwidth of the HDR signal.

In the sensor-side transceiver, for example, Low-Pass Filtering (LPF) in the LDR receiver filters-out most of the energy of the HDR signal. In other words, the amount of energy of the HDR signal that falls within the bandwidth of the LDR signal is small. In the switch-side transceiver, LPF in the LDR transmitter considerably reduces the echo of the LDR signal received by the HDR receiver.

Another mechanism that assists in the successful decoding of the HDR signal is proper choice of transmission power levels for the HDR and LDR signals. In some embodiments, the nominal transmission power of the LDR signal (at the output of LDR TX 68) is set to be lower than the nominal transmission power of the HDR signal (at the output of HDR TX 56). In one example embodiment, when using an STP cable, the nominal transmission power of the HDR signal is set to 0 dBm, while the nominal transmission power of the LDR signal is set to −6 dBm (i.e., the LDR signal power is 25% of the HDR signal power). In another example embodiment, when using a coaxial cable, the nominal transmission power of the HDR signal is set to −3 dBm, while the nominal transmission power of the LDR signal is set to −9 dBm (the LDR signal power is again 25% of the HDR signal power). In alternative embodiments, other suitable power levels can be used.

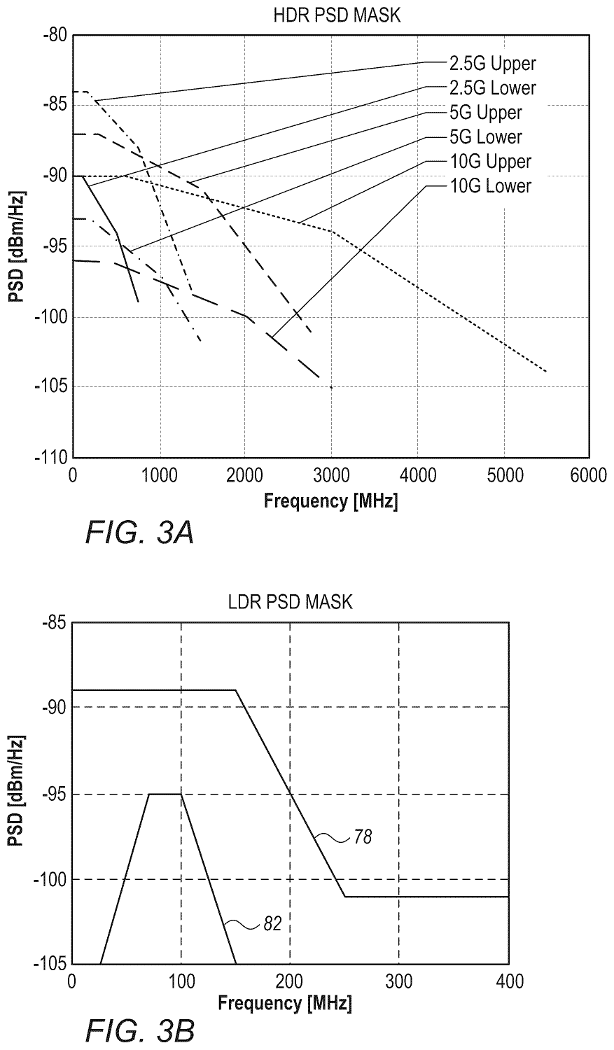

FIG. 3A is a graph showing power spectrum masks for HDR signals used in ACT, in accordance with embodiments that are described herein. Different line styles mark the maximum and minimum allowed PSD for the 2.5 Gbps, 5 Gbps and 10 Gbps data rates, as a function of frequency.

FIG. 3B is a graph showing a power spectrum mask for the LDR signal used in ACT, in accordance with an embodiment that is described herein. Plots 78 and 82 mark the respective maximum and minimum allowed PSD for the 100 Mbps LDR signal as a function of frequency.

### Example Act Transceiver Implementations

FIG. 4A is a block diagram that schematically illustrates an example implementation of a switch-side (network-side) ACT transceiver, in accordance with embodiments that are described herein. This design can be used for implementing transceiver 48B of FIG. 1 above.

In the present example, transceiver 48B comprises three modules—an Analog Front-End (AFE) 86, a Digital Physical Medium Attachment module (PMA) 90, and a Physical Coding Sublayer module (PCS) 94.

AFE 86 comprises a hybrid splitter/combiner 98 that receives the HDR signal from MDI 52 (see FIG. 1) and sends the LDR signal to the MDI. From this point the processing splits into an HDR reception path and an LDR transmission path.

In the HDR reception path (seen at the bottom of FIG. 4A), the received HDR signal is filtered by analog RX filters 102, and then digitized by an Analog-to-Digital Converter (ADC) 106. The digital HDR signal is provided to PMA 90.

In PMA 90, the digital HDR signal is equalized by a Feed-Forward Equalizer (FFE) 110, sliced by a slicer 114, and further equalized by a Decision-Feedback Equalizer (DFE) 118. Slicer 114 outputs a sequence of PAM4 symbol decisions (four possible 2-bit values corresponding to the PAM4 “−3”, “−1”, “1” and “3” symbols). The PAM4 symbol decisions are provided to PCS 94.

In PCS 94, a PAM demapper 122 converts each 2-bit symbol decision into two information bits. A Forward Error Correction (FEC) decoder & de-interleaver 126 decodes the FEC used by the HDR transmitter and performs de-interleaving (the FEC encoding and interleaving operations in the HDR transmitter are addressed in the description of FIG. 4B below). A framing and Operations, Administration, and Maintenance (OAM) module 130 extracts received bits from the received bit stream according to Ethernet framing. Module 130 separates between OAM information and user information, and outputs the information from transceiver 48B.

The LDR transmission path (seen at the top of FIG. 4A) begins with a framing and OAM module 134. Module 134 receives OAM information and user information for transmission, and constructs Ethernet frames. A FEC & interleaver module 138 encodes the frames using a suitable FEC, and interleaves the encoded bit stream. A DME mapper 142 modulates the bit stream using DME. As noted above, mapper 142 maps one bit value (e.g., “1”) to a first symbol type having a level transition in the middle of the symbol interval; and maps the opposite bit value (e.g., “0”) to a second symbol type having a constant level across the symbol interval. The modulated DME signal is provided to AFE 86 via PMA 90.

In some embodiments, although not necessarily, PMA 90 performs a modest amount of echo cancellation to assist demodulation of the HDR signal. In these embodiments, PMA 90 comprises an Echo Canceler (EC) 154 that injects a replica of the LDR signal into the HDR reception path (after proper matching in gain and phase to allow cancellation of the echo). As seen in the figure, injection can be performed at various points in the HDR reception path. In some embodiments, EC 154 is omitted.

In AFE 86, the modulated digital LDR signal is converted into an analog signal by a Digital-to-Analog Converter (DAC) 146. An analog TX filter 150 filters the DAC output, and the resulting LDR signal is sent via hybrid 98 to MDI 52 (and onwards to link 40).

FIG. 4B is a block diagram that schematically illustrates an example implementation of a sensor-side (e.g., camera-side) ACT transceiver, in accordance with embodiments that are described herein. This design can be used for implementing transceiver 48A of FIG. 1 above. In the present example, transceiver 48A comprises three modules—an AFE 158, a Digital PMA 92 and a PCS 96.

AFE 158 comprises a hybrid splitter/combiner 98 that receives the LDR signal from MDI 52 (see FIG. 1) and sends the HDR signal to the MDI. From this point the processing splits into an LDR reception path and an HDR transmission path.

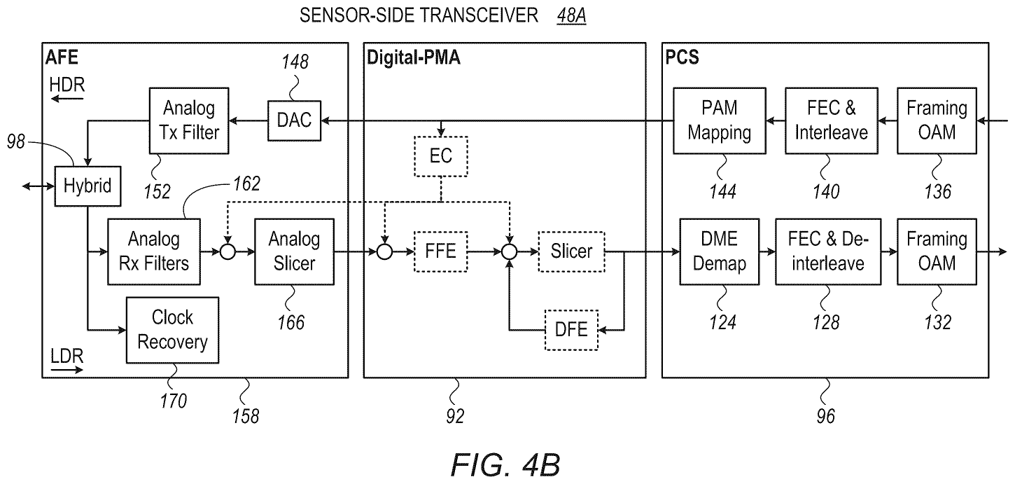

In the LDR reception path (seen at the bottom of FIG. 4B), the received LDR signal is provided to a clock recovery module 170. Aspects of clock recovery are addressed in detail below, with reference to FIG. 5. The received LDR signal is also filtered by analog RX filters 162 and then demodulated by a slicer 166. Slicer 166 quantizes the received signal to two levels. The slicer output is provided to PCS 94 via PMA 90.

In PCS 94, a DME demapper 124 converts the sliced signal into a stream of “0” and “1” bit values, in accordance with the DME mapping. In an example embodiment, demapper 124 outputs a “1” bit value upon identifying a level transition in the middle of a symbol interval; and outputs a “0” bit value upon identifying a symbol interval in which the signal level is constant. A FEC & de-interleaver 128 decodes the FEC used by the LDR transmitter and performs de-interleaving. A framing and OAM module 132 extracts received bits from the received bit stream, separates between OAM information and user information, and outputs the information from transceiver 48A.

The HDR transmission path (seen at the top of FIG. 4B) begins with a framing and OAM module 136. Module 136 receives OAM information and user information for transmission, and constructs suitable frames. A FEC & interleaver module 140 encodes the frames using a suitable FEC, and interleaves the encoded bit stream. A PAM mapper 144 modulates the bit stream onto 4-level PAM4 symbols. The resulting digital PAM4 signal is provided to AFE 158 via PMA 92.

In AFE 158, a DAC 148 converts the digital PAM4 signal into an analog signal. An analog TX filter 152 filters the analog signal. The filtered signal is sent via hybrid 98 to MDI 52, and onwards to link 40.

In the present example of FIG. 4B, PMA functions such as equalization and echo cancellation are not needed for properly demodulating the LDR signal. In this embodiment the corresponding modules (FFE, DFE and EC) are omitted, and they are therefore shown as dashed in the figure. This is highly desirable for reducing the cost, size and power consumption of the sensor-side PHY device. In alternative embodiments, however, some extent of equalization and/or a certain degree of echo cancellation may be required. In such embodiments, PMA 92 may comprise an FFE, a DFE and/or an EC as needed.

### Crystal-Less Operation in Sensor-Side Phy Device

Both sensor-side transceiver 48A and switch-side transceiver 48B typically need suitable clock signals for transmitting and receiving the HDR and LDR signals. In some embodiments, sensor-side transceiver 48A is implemented without using any local crystal oscillator for clock generation. Instead, sensor-side transceiver 48A uses a clock signal recovered from the received LDR signal. This “crystal-less” configuration reduces the cost, size, component count and power consumption of sensor-side PHY device 36A.

In a typical crystal-less configuration, clock circuitry in the sensor-side transceiver recovers an LDR clock signal from the received LDR signal, and uses the LDR clock signal to generate an HDR clock signal used for HDR transmission.

FIG. 5 is a block diagram that schematically illustrates crystal-less clock circuitry in sensor-side ACT transceiver 48A, in accordance with an embodiment that is described herein. In the present example, transceiver 48A comprises a Clock and Data Recovery (CDR) module 180, which extracts a 100 Mbps clock signal (referred to as “LDR clock signal”) from the received LDR signal.

A Phase-Locked Loop (PLL) 188 uses the 100 Mbps clock signal to generate a HDR clock signal. The frequency of the HDR clock signal depends on the data rate of the HDR signal (e.g., 2.5 Gbps, 5 Gbps or 10 Gbps). In the present example a 10 Gbps clock signal is used. In an embodiment, a Clock Management Unit (CMU) 184 configures PLL 188 with the proper scaling factors between the LDR clock signal and the HDR clock signal, depending on the desired data rate of the HDR signal. A data extraction module 192 extracts the data from the received LDR signal.

### Method Description

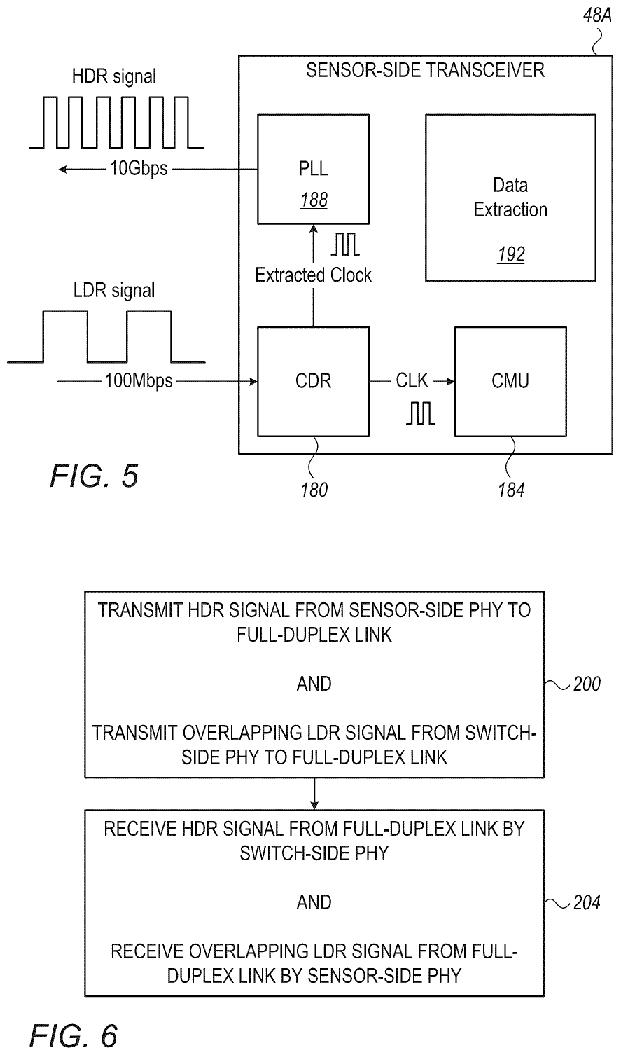

FIG. 6 is a flow chart that schematically illustrates a method for communication using ACT, in accordance with an embodiment that is described herein. At a transmission stage 200, HDR transmitter 56 in sensor-side PHY device 36A transmits an HDR signal, and LDR transmitter 68 in switch-side PHY device 36B transmits an LDR signal. Both signals are transmitted simultaneously (and typically continuously) over full-duplex link 40. At a reception stage 204, HDR receiver 64 in switch-side PHY device 36B receives the HDR signal, and LDR receiver 60 in sensor-side PHY device 36A receives the LDR signal.

The configurations of system 20 and of the various PHY devices and their components, as shown in FIGS. 1, 4A, 4B and 5, are example configurations that are depicted solely for the sake of clarity. In alternative embodiments, any other suitable configurations can be used. The different elements of the disclosed PHY devices may be implemented using dedicated hardware or firmware, such as using hard-wired or programmable logic, e.g., in an Application-Specific Integrated Circuit (ASIC) or Field-Programmable Gate Array (FPGA). Additionally, or alternatively, some functions of the disclosed PHY devices may be implemented in software and/or using a combination of hardware and software elements. Elements that are not mandatory for understanding of the disclosed techniques have been omitted from the figure for the sake of clarity.

In some embodiments, some functions of the disclosed PHY devices may be implemented in one or more programmable processors, e.g., one or more Central Processing Units (CPUs), microcontrollers and/or Digital Signal Processors (DSPs), which are programmed in software to carry out the functions described herein. The software may be downloaded to any of the processors in electronic form, over a network, for example, or it may, alternatively or additionally, be provided and/or stored on non-transitory tangible media, such as magnetic, optical, or electronic memory.

Although the embodiments described herein mainly address asymmetric Ethernet links in an automotive network, the methods and systems described herein can also be used in other applications, such as in other communication links having asymmetric traffic, e.g., a link between a processor and a display.

It is noted that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. A Physical Layer (PHY) device for use in an Ethernet network in a vehicle, the PHY device comprising:
a link interface, configured to connect to a full-duplex Ethernet link; and
a transceiver, configured to:
communicate over the full-duplex Ethernet link in a first direction using a High-Data-Rate (HDR) signal having a first data rate; and
communicate over the full-duplex Ethernet link in a second direction, opposite to the first direction, using a Low-Data-Rate (LDR) signal having a second data rate, lower than the first data rate,
wherein a frequency spectrum of the LDR signal is contained within a frequency spectrum of the HDR signal.

2. The PHY device according to claim 1, wherein the LDR signal is modulated with Differential Manchester Encoding (DME) modulation.

3. The PHY device according to claim 1, wherein a transmitted power level of the LDR signal is lower than a transmitted power level of the HDR signal.

4. The PHY device according to claim 1, wherein the full-duplex Ethernet link is a two-wire twisted-pair link.

5. The PHY device according to claim 1, wherein the full-duplex Ethernet link is a coaxial cable.

6. The PHY device according to claim 1, wherein the transceiver is configured to transmit the HDR signal to the full-duplex Ethernet link, and to receive the LDR signal from the full-duplex Ethernet link.

7. The PHY device according to claim 6, wherein the transceiver is configured to demodulate the LDR signal in the presence of the transmitted HDR signal, without applying echo cancellation.

8. The PHY device according to claim 6, wherein the transceiver is configured to extract a LDR clock signal from the received LDR signal, to generate a HDR clock signal that is locked on the LDR clock signal, and to transmit the HDR signal in accordance with the HDR clock signal.

9. The PHY device according to claim 8, wherein the transceiver is configured to generate the HDR clock signal without a local crystal oscillator.

10. The PHY device according to claim 1, wherein the transceiver is configured to transmit the LDR signal to the full-duplex Ethernet link, and to receive the HDR signal from the full-duplex Ethernet link.

11. The PHY device according to claim 10, wherein the transceiver is configured to demodulate the HDR signal in the presence of the transmitted LDR signal, without applying echo cancellation.

12. The PHY device according to claim 1, wherein a baud rate of the LDR signal is approximately 117 Mbaud.

13. A method for communication in an Ethernet network in a vehicle, the method comprising:
communicating over a full-duplex Ethernet link in a first direction using a High-Data-Rate (HDR) signal having a first data rate; and
communicating over the full-duplex Ethernet link in a second direction, opposite to the first direction, using a Low-Data-Rate (LDR) signal having a second data rate, lower than the first data rate,
wherein a frequency spectrum of the LDR signal is contained within a frequency spectrum of the HDR signal.

14. The method according to claim 13, wherein the LDR signal is modulated with Differential Manchester Encoding (DME) modulation.

15. The method according to claim 13, wherein a transmitted power level of the LDR signal is lower than a transmitted power level of the HDR signal.

16. The method according to claim 13, wherein the full-duplex Ethernet link is a two-wire twisted-pair link.

17. The method according to claim 13, wherein communicating over the full-duplex Ethernet link comprises transmitting the HDR signal to the full-duplex Ethernet link, and receiving the LDR signal from the full-duplex Ethernet link.

18. The method according to claim 17, wherein communicating over the full-duplex Ethernet link comprises demodulating the LDR signal in the presence of the transmitted HDR signal, without applying echo cancellation.

19. The method according to claim 17, wherein communicating over the full-duplex Ethernet link comprises extracting a LDR clock signal from the received LDR signal, generating a HDR clock signal that is locked on the LDR clock signal, and transmitting the HDR signal in accordance with the HDR clock signal.

20. The method according to claim 13, wherein communicating over the full-duplex Ethernet link comprises transmitting the LDR signal to the full-duplex Ethernet link, and receiving the HDR signal from the full-duplex Ethernet link.
